(19) United States
(12) Patent Application Publication
(10) Pub. No.: US 2004/0211458 A1
(43) Pub. Date: Oct. 28, 2004

(54) Tandem photovoltaic cell stacks

(75) Inventors: John Yupend Gui, Niskayuna, NY (US); Robert Louis Steigerwald, Burnt Hills, NY (US); Donald Earl Castleberry, Niskayuna, NY (US)

Correspondence Address: General Electric Company, CRD Patent Docket Rm 4A59, Bldg. K-1, P.O. Box 8, Schenectady, NY, 12301, US

(73) Assignee: General Electric Company

(21) Appl. No.: 10/424,276

(22) Filed: Apr. 28, 2003

(51) Int. Cl. H01L 31/00

(52) U.S. Cl. 136/244; 136/249; 136/255

(57) ABSTRACT

A photovoltaic (“PV”) device comprises a plurality of PV cell modules arranged in tandem. Each of the plurality of the tandem PV cell modules comprises at least a PV cell that comprises a pair of electrodes, at least one of which is substantially transparent to the light received by the PV device; an electron donor material, which is a photoactivatable material; and an electron acceptor material. The electron donor material of each of the plurality of the tandem PV cell modules is capable of absorbing a different portion of the spectrum of light received by the PV device.

### BACKGROUND OF THE INVENTION

The present invention relates to photovoltaic energy sources having improved optical and electrical efficiency. In particular, the present invention relates to stacks of tandem photovoltaic cells electrically connected in parallel.

Solar energy has increasingly become an attractive source of energy for remote locations and has been recognized as a clean, renewable alternative form of energy. Solar energy in the form of sunlight, in one scheme, is converted to electrical energy by solar cells. A more general term for devices that convert light to electrical energy is “photovoltaic cells.” Sunlight is a subset of light. Thus, solar cells are a subset of photovoltaic cells. A photovoltaic cell comprises a pair of electrodes and a light-absorbing photovoltaic material disposed therebetween. When the photovoltaic material is irradiated with light, electrons that have been confined to an atom in the photovoltaic material are released by light energy to move freely. Thus, free electrons and holes are generated. The free electrons and holes are efficiently separated so that electric energy is continuously extracted. Current commercial photovoltaic cells use a semiconductor photovoltaic material, typically silicon. However, silicon for photovoltaic cells requires high purity and stringent processing methods.

One type of photovoltaic cells, which have been developed recently, is dye-sensitized photovoltaic cells. These cells use semiconductor materials that have less stringent requirements than silicon. One such material is titanium dioxide. However, titanium dioxide absorbs little photon energy from sunlight, and thus requires a dye (or chromophore) as a sensitizing agent in close coupling with the semiconductor solid (e.g. titanium dioxide). When a dye molecule absorbs a photon, electrons are excited into the lowest unoccupied molecular orbital, from which they are injected into the conduction band of the semiconductor (e.g., titanium dioxide), and flow through the first electrode (sometimes also known as the solar electrode or electron-generating electrode). Thus, the semiconductor serves as a transport medium for electrons, and does not require high purity, as does silicon in silicon-based photovoltaic cells. Charge transport between the semiconductor/dye layer and the second electrode (or counter electrode) occurs through an electrolyte solution. The returning electrons at the second electrode effect an oxidation-reduction (“redox”) reaction, generating a charged species that returns the electrons to the excited, oppositely charged dye molecules, and the cycle repeats. It is very desirable to provide a sensitizing agent that absorb as large a portion of the sunlight wavelength as possible to maximize the harvest of photon energy for a single photovoltaic cell device.

Transition metal complexes, such as Ru(II)(2,2′-bipyridyl-4,4′dicarboxylate)₂(NCS)₂, have been found to be efficient sensitizers and can be attached to the semiconductor metal oxide solid through carboxyl or phosphonate groups located on the periphery of the compounds. These metal complexes typically have extinction coefficients for absorption (or absorptivities) on the order of 1-3×10⁴ M⁻¹ cm⁻¹. Organic dyes, such as the dyes of the rhodamine, cyanine, coumarin, or xanthene families, on the other hand, have higher extinction coefficients for absorption, on the order of 10⁵ M⁻¹ cm⁻¹. However, organic dyes typically absorb only a narrow range (less than about 100 nm, more typically less than about 50 nm) of the sunlight spectrum and, therefore, are not efficient sensitizers for photovoltaic cells.

Therefore, there is still a need to provide photovoltaic cells that can harvest most of the sunlight photon energy. Moreover, it is very desirable to provide energy-efficient photovoltaic cells that can take advantage of the high absorptivities of organic dye sensitizers.

### SUMMARY OF THE INVENTION

The present invention provides a photovoltaic device that comprises a plurality of photovoltaic cell modules arranged in tandem. Each of the plurality of tandem photovoltaic (“PV”) cell modules comprises at least a photovoltaic cell that comprises a first electrode, a second electrode, an electron donor material, and an electron acceptor material. The electron donor material is photoactivatable; i.e., a material that can release free electrons upon absorbing photon energy and becoming excited to a higher energy level. An electron acceptor material can accept electrons from the counter electrode and release or deliver electrons to the electron donor material. The electron donor material and the electron acceptor material are in contact with one another and are disposed between the first and second electrodes to inject electrons to or to accept electrons from one of the electrodes. Each of the electron donor materials of the plurality of tandem PV cell modules absorbs a different portion of the spectrum of the exciting radiation, and all of the electron donor materials of the plurality of tandem PV cells together preferably absorb substantially the whole spectrum of the exciting radiation.

In one embodiment of the present invention, the electron donor material is a photoactivatable dye closely coupled with a semiconductor solid that is disposed in electrical contact with the first electrode, and the electron acceptor material is an electrolyte that is capable of undergoing an oxidation-reduction reaction and is disposed in a space between the first and second electrodes. The photoactivatable dye of each of the plurality of tandem photovoltaic cell modules absorbs a different portion of the spectrum of the exciting radiation, and the photoactivatable dyes of all of the tandem photovoltaic cell modules together absorb substantially the whole spectrum of the exciting radiation.

In another aspect of the present invention, the photoactivatable dye is ads orbed on the semiconductor solid.

In still another aspect of the present invention, the electron donor material and the electron acceptor material are organic semiconducting polymers, forming a p-n junction.

In still another aspect of the present invention, the electron donor material is a photoactivatable dye, and the electron acceptor material is an organic semiconducting polymer.

In still another aspect of the present invention, the exciting radiation is sunlight, having wavelengths in the range from about 290 nm to about 2500 nm, and more particularly, from about 290 nm to about 820 nm, which is the wavelength range of the more energetic photons.

In still another aspect of the present invention, all of the photovoltaic cells of each photovoltaic cell module comprise one type of photoactivatable dye. The photovoltaic cells are electrically connected to provide maximum power from each module, as measured by the product of current and voltage supplied from the module.

In still another aspect of the present invention, the photovoltaic cells of each photovoltaic cell module are electrically connected to provide a specific voltage or current requirement from the module.

Other features and advantages of the present invention will be apparent from a perusal of the following detailed description of the invention and the accompanying drawings in which the same numerals refer to like elements.

### BRIEF DESCRIPTION OF THE DRAWINGS

It should be understood that the figures accompanying this disclosure are not drawn to scale.

FIG. 1 shows typical components of a dye-sensitized PV cell.

FIG. 2 shows typical components of an organic PV cell comprising organic semiconducting materials.

FIG. 3 shows a PV device of the present invention, the photovoltaic device comprising a stack of dye-sensitized PV cells arranged in tandem.

FIG. 4 illustrates a PV device comprising a stack of PV cell modules, each module comprising a plurality of PV cells arranged on a support.

FIG. 5 shows the characteristic current-voltage and power density curves for a typical PV cell.

FIG. 6 shows schematically a first system implementing the use of tandem PV cell modules to extract maximum power from each of the modules independently.

FIG. 7 shows schematically a second system implementing the use of tandem PV cell modules wherein one converter is used to extract maximum power from two PV cell modules.

FIG. 8 shows schematically a third system implementing the use of tandem PV cell modules wherein maximum is extracted from one module.

FIG. 9 shows the characteristic current-voltage and power density curves of a dye-sensitized PV cell of the present invention.

FIG. 10 shows the normalized quantum efficiency of a dye-sensitized PV cell of the present invention.

### DETAILED DESCRIPTION OF THE INVENTION

The following definitions are used throughout the present disclosure. The term “substantially transparent” means allowing at least 80 percent of light having wavelengths in the range from about 290 nm to about 2500 nm to be transmitted through a film having a thickness of about 0.5 micrometer at an incident angle less than about 10 degrees. The terms “light,” “radiation,” and “electromagnetic radiation” are used interchangeably to mean electromagnetic (“EM”) radiation having wavelength in the range from about 290 nm to about 2500 nm.

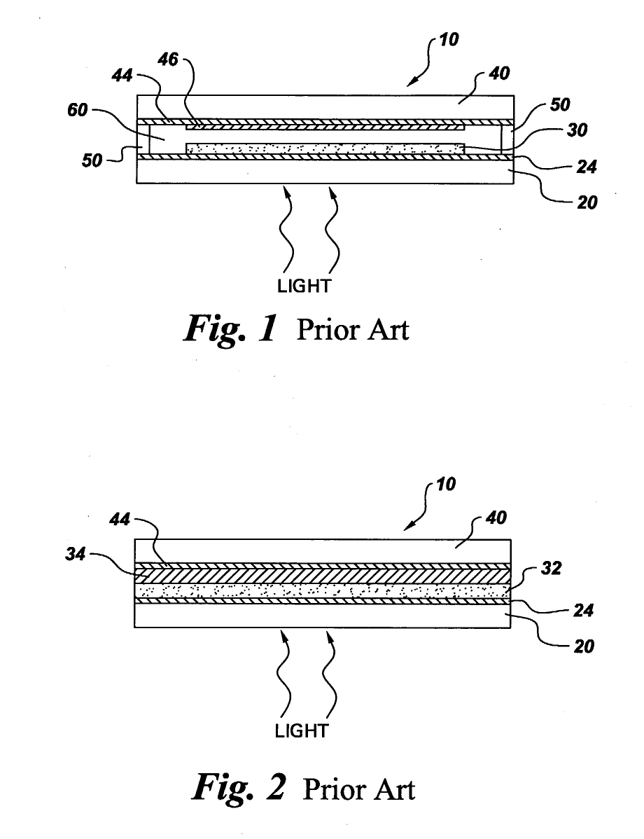

FIG. 1 shows the components of a typical dye-sensitized photovoltaic cell (“DSPVC”) 10. Substantially transparent substrate 20 has a coating 24 on one of its surface. Coating 24 comprises a substantially transparent, electrically conductive material, which serves as the first electrode of DSPVC 10. Suitable materials that can be used for coating 24 are substantially transparent conductive oxides, such as indium tin oxide (“ITO”), tin oxide, indium oxide, zinc oxide, indium zinc oxide, zinc indium tin oxide, antimony oxide, and mixtures thereof. A substantially transparent layer, a thin film, or a mesh structure of metal such as silver, gold, platinum, titanium, aluminum, copper, steel, or nickel is also suitable.

Substantially transparent substrate 20 is made of glass or polymeric materials. Suitable polymeric materials are polyethyleneterephthalate (“PET”), polyacrylates, polycarbonates, polyesters, polysulfones, polyetherimides, silicone, epoxy resins, and silicone-functionalized epoxy resins.

A semiconductor layer 30 is disposed in electrical contact with coating 24. Suitable semiconductors for layer 30 are metal oxide semiconductors, such as oxides of the transition metals, and oxides of the elements of Groups III, IV, V, and VI of the Periodic Table; specifically, oxides of titanium, zirconium, halfnium, strontium, zinc, indium, yttrium, lanthanum, vanadium, niobium, tantalum, chromium, molybdenum, tungsten, iron, nickel, silver or mixed oxides of these elements. Other suitable oxides are those having a perovskite structure, such as SrTiO₃ or CaTiO₃. The semiconductor material of layer 30 is coated by adsorption of a photosensistizing dye on the surface thereof. Preferably, the photoactivatable dye is chemically adsorbed on or bonded through chemical bonds to the surface of the semiconductor material. Such chemical bonds are easily formed when the photoactivatable dye has a functional group such as carboxyl, alkoxy, hydroxy, hydroxyalkyl, sulfonic, phosphonyl, ester, or mercapto groups. Non-limiting examples of photoactivatable dyes are organometallic complexes having a formula of MX₃Lₜ or MXYLₜ, where Lₜ is tridentate ligand comprising heterocycles such, as pyridine, thiophene, imidazole, pyrazole, triazole, carrying at least one carboxylic, phosphoric, hydroxamic acid or chelating groups; X is a co-ligand independently selected from the group consisting of NCS, Cl, Br, I, CN, NCO, H₂O, NCH, pyridine unsubstituted or substituted with at least one group selected from the group consisting of vinyl, primary amine, secondary amine, and tertiary amine, OH, and C₁₋₃₀ alkyl; and Y is a co-ligand selected from the group consisting of o-phenanthroline, 2,2′-bipyridine unsusbtituted or substituted with at least one C₁₋₃₀ alkyl group. Other suitable photoactivatable dyes are the organic dyes or other organometallic dyes, such as azo dyes, quinone dyes, quinoneimine dyes, quinacridone dyes, squarylium dyes, cyanine dyes, merocyanine dyes, triphenylmethane dye, xanthene dyes, porphyrin dyes, phthalocyanine dyes, perylene dyes, indigo dyes, and naphthalocyanine dyes. The photoactivatable dyes acts as an electron donor material.

A second substrate 40 having an electrically conductive coating 44 disposed thereon is disposed opposite and apart from semiconductor layer 30. Electrically conductive coating 44 serves as the second electrode of DSPVC 10, and can be made of one of the conductive oxides listed above or of a metal layer. Substrate 40 may be made of a substantially transparent glass or polymeric material. A layer 46 of a catalyst for oxidation-reduction reaction is disposed on coating 44. Suitable catalysts for oxidation-reduction reaction are platinum and palladium. It is preferred that the catalyst metals are disposed as very fine particles, such as having a size on the order of less than about 10 nanometers.

Seals 50 are provided around the periphery of DSPVC 10 to define space 60, which contains an electrolyte, which serves as a charge carrier for returning electrons from an external circuit. The electrolyte comprises a species that can undergo oxidation-reduction reaction, thus acting as an electron acceptor material, such a combination of an iodide salt and iodine, or a bromide salt and bromine. Salts such as LiI, NaI, KI, Cal₂, LiBr, NaBr, KBr, or CaBr₂ are often used. Seals 50 are made of a material resistant to chemical attack by the electrolyte, such as an epoxy resin.

A second type of organic PV cells Is shown schematically in FIG. 2. Organic PV cell 10 comprises an organic electron donor material and an electron acceptor material. Substantially transparent substrate 20 has a coating 24 on one of its surface. Coating 24 comprises a substantially transparent, electrically conductive material, which serves as the first electrode of organic PV cell 15. Suitable materials that can be used for coating 24 are substantially transparent conductive oxides, such as ITO, tin oxide, indium oxide, zinc oxide, indium zinc oxide, zinc indium tin oxide, antimony oxide, and mixtures thereof. A thin, substantially transparent layer of metal such as silver, gold, aluminum, copper, steel, or nickel is also suitable.

Substantially transparent substrate 20 is made of glass or polymeric materials. Suitable polymeric materials are polyethyleneterephthalate (“PET”), polyacrylates, polycarbonates, polyesters, polysulfones, polyetherimides, silicone, epoxy resins, and silicone-functionalized epoxy resins.

A layer 32 of an electron donor organic material is disposed in electrical contact with first electrode 24. Suitable electron donor organic materials are polymers that can provide freely moving electrons upon absorbing photon energy and becoming excited to a higher energy level. Such electron donor materials typically do not comprise electron-withdrawing groups, such as polyphenylene, poly(phenylene vinylene), polythiophene, polysilane, poly(thienylene vinylene), poly(isothianaphthene), derivatives thereof, and copolymers thereof.

A layer 34 of an electron acceptor organic material is disposed in electrical contact with layer 32. Suitable electron acceptor organic materials are polymers that typically comprise a electron-withdrawing group, such as poly(phenylene vinylene) or its derivatives that contain CN or CF₃ groups. Layers 32 and 34 can be deposited on underlying layer by a method selected from the group consisting of physical vapor deposition, chemical vapor deposition, spin coating, dip coating, spraying, printing (such as ink-jet printing or screen printing), and doctor blading.

A second electrode 44 is disposed in electrical contact with layer 34 of the electron acceptor material. Second electrode 44 can comprise a conducting metal oxide chosen among those disclosed above or a thin layer of a metal, such as silver, gold, copper, aluminum, steel, or nickel. It can be desirable to choose a material that has a low work function, such as K, Li, Na, Mg, La, Ce, Ca, Sr, Ba, Al, Ag, In, Sn, Zn, Zr, Sm, Eu, an alloy thereof, or a mixture thereof. The material for second electrode 44 can be deposited on layer 34 by a method selected from the group consisting of physical vapor deposition and chemical vapor deposition. Alternatively, the material for second electrode 44 can be deposited on substrate 40, and the resulting coated substrate can be laminated to substrate 20 that already has layers 23, 32, and 34 formed thereon.

In another aspect of the present invention, the electron donor material of layer 32 can comprise a photoactivatable dye selected from the group of dyes disclosed for DSPVC 10 above.

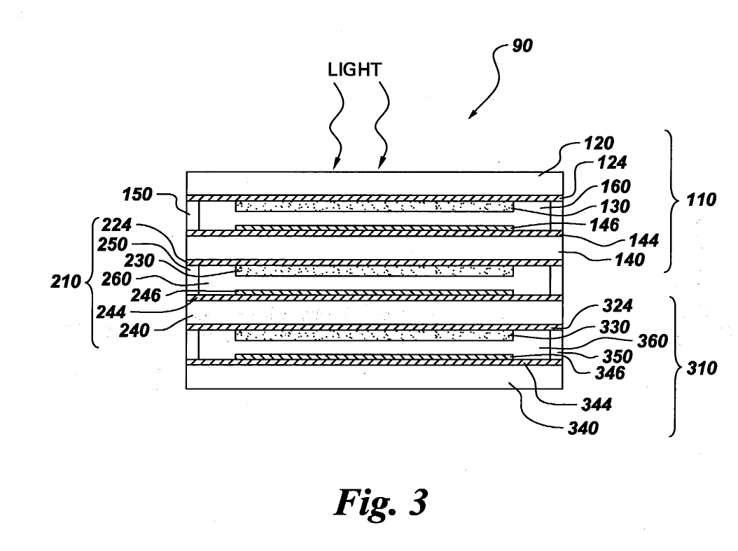

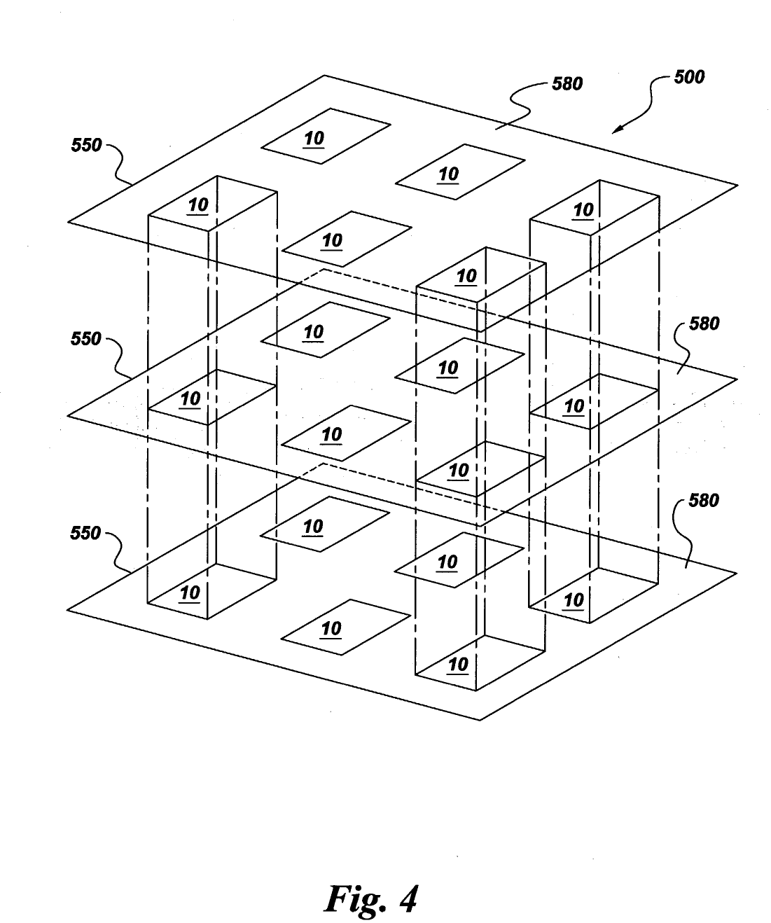

FIG. 3 illustrates a PV device 90 of the first embodiment of the present invention that comprises a plurality of PV cell modules arranged in tandem. Although FIG. 3 shows three PV cell modules 110, 210, and 310, it should be understood that the present invention is applicable for any number of modules greater than 2. In addition, although FIG. 3 shows only one PV cell for each PV cell module, a PV cell module of the present invention can comprise a plurality of PV cells arranged on a larger support, as will be disclosed below in connection with FIG. 4. The first PV cell module 110 comprises a first substantially transparent substrate 120, which is exposed to light and is made of a glass or a substantially transparent polymeric material. Suitable polymeric materials are polyethyleneterephthalate (PET), polyacrylates, polycarbonates, polyesters, polysulfones, polyetherimides, silicone, epoxy resins, and silicone-functionalized epoxy resins. A coating 124 comprising a substantially transparent, electrically conductive material that serves as the first electrode for PV cell module 110. Suitable materials that can be used for coating 24 are substantially transparent, electrically conductive oxides, such as indium tin oxide (ITO), tin oxide, indium oxide, zinc oxide, indium zinc oxide, zinc indium tin oxide, antimony oxide, and mixtures thereof. A thin, substantially transparent layer of metal is also suitable. Such a metal layer typically has a thickness of less than 100 nm, preferably less than 50 nm. Suitable metals are silver, gold, aluminum, copper, steel, or nickel.

A semiconductor layer 130 is disposed in electrical contact with coating 124. Suitable semiconductors for layer 130 are metal oxide semiconductors, such as oxides of the transition metal elements; specifically, oxides of titanium, zirconium, halfnium, strontium, zinc, indium, yttrium, lanthanum, vanadium, niobium, tantalum, chromium, molybdenum, tungsten, iron, nickel, silver or mixed oxides of these elements. Other suitable oxides are those having a perovskite structure, such as SrTiO₃ or CaTiO₃. The semiconductor material of layer 130 is coated by adsorption of a photosensistizing dye on the surface thereof. Preferably, the photoactivatable dye is chemically adsorbed on or bonded through chemical bonds to the surface of the semiconductor material. Such chemical bonds are easily formed when the photoactivatable dye has a functional group such as carboxyl, alkoxy, hydroxy, hydroxyalkyl, sulfonic, phosphonyl, ester, or mercapto groups. Non-limiting examples of photoactivatable dyes are organometallic complexes having a formula of MX₃Lₜ or MXYLₜ, where M is a transition metal selected from the group consisting of ruthenium, osmium, iron, rhenium, and technetium; Lₜ is tridentate ligand comprising heterocycles such as pyridine, thiophene, imidazole, pyrazole, triazole, carrying at least one carboxylic, phosphoric, hydroxamic acid or chelating groups; X is a co-ligand independently selected from the group consisting of NCS, Cl, Br, I, CN, NCO, H₂O, NCH, pyridine unsubstituted or substituted with at least one group selected from the group consisting of vinyl, primary amine, secondary amine, and tertiary amine, OH, and C₁₋₃₀ alkyl; and Y is a co-ligand selected from the group consisting of o-phenanthroline, 2,2′-bipyridine unsusbtituted or substituted with at least one C₁₋₃₀ alkyl group. Other suitable photoactivatable dyes are the organic dyes or other organometallic dyes, such as azo dyes, quinone dyes, quinoneimine dyes, quinacridone dyes, squarylium dyes, cyanine dyes, merocyanine dyes, triphenylmethane dyes, xanthene dyes, porphyrin dyes, phthalocyanine dyes, perylene dyes, indigo dyes, and naphthalocyanine dyes.

A second substrate 140 having an electrically conductive coating 144 disposed on a first surface thereof is disposed opposite and apart from semiconductor layer 130. Electrically conductive coating 144 serves as the second electrode of DSPVC 110, and can be made of one of the conductive oxides or of a substantially transparent layer of one of the metals listed above for the first electrode layer 124. Substrate 140 may be made of a substantially transparent glass or polymeric material, such as one of the polymeric materials listed above. A layer 146 of a catalyst for oxidation-reduction reaction is disposed on coating 144. Suitable catalysts for oxidation-reduction reaction are platinum and palladium. It is preferred that the catalyst metals are disposed as very fine particles, such as having a size on the order of less than about 10 nanometers.

Seals 150 are provided around the periphery of DSPVC 110 to define space 160, which contains an electrolyte, which serves as a charge carrier for returning electrons from an external circuit. The electrolyte comprises a species that can undergo oxidation-reduction reaction, such a combination of an iodide salt and iodine, or a bromide salt and bromine. Salts such as LiI, NaI, KI, Cal₂, LiBr, NaBr, KBr, or CaBr₂ are often used. Seals 150 are made of a material resistant to chemical attack by the electrolyte, such as an epoxy resin.

Substantially transparent substrate 140 also serves as the first substrate for the second PV cell 210, and provides electrical isolation from the first PV cell 110. Substrate 140 has a coating 224 of a substantially transparent, electrically conductive material that is selected from among the materials disclosed above (for layer 124) and disposed on the second surface thereof. Thus, cells 210 is electrically insulated from cell 110. Each of the second and third PV cells 210 and 310 has similar components as the first PV cell 110. The components of PV cells 210, and 310 comprise materials that are disclosed as suitable for the corresponding components of PV cell 110. However, corresponding components of PV cells 110, 210, and 310 may not comprise the same material.

A semiconductor layer 230 is disposed on coating 224. The semiconductor material of layer 230 is coated by adsorption of a photoactivatable dye on the surface thereof. The photoactivatable dye for each of PV cells 110, 210, and 310 is capable of absorbing light of a different wavelength range in the spectrum of total light received by PV device 90 so that cells 110, 210, and 310 together absorb substantially all of the light received by device 90. In other words, the spectrum of total light received by device 90 comprises the wavelength ranges of light absorbed by all of the photoactivatable dyes of cells 110, 210, and 310. For example, when the total light received by device 90 is sunlight, the photoactivatable dyes for PV cells 110, 210, and 310 may be chosen to have substantial absorption in the range of about 430-530 nm, 530-580 nm, 580-700 nm, respectively. In addition, one or more additional PV cells may be included in device 90, which additional PV cells carry photoactivatable dyes having substantial absorption in a portion of the UV range, such as 290-400 nm, or in the near infrared range, such as 700-820 nm. Since each PV cell is manufactured to absorb light maximally in a different wavelength range, the energy conversion efficiency of the total device 90 can be improved significantly over that of prior art devices.

A second substrate 240 having an electrically conductive coating 244 disposed on a first surface thereof is disposed opposite and apart from semiconductor layer 230. Electrically conductive coating 244 serves as the second electrode of DSPVC 210, and can be made of one of the conductive oxides listed above or of a substantially transparent metal layer. Substrate 240 may be made of a substantially transparent glass or polymeric material, such as one of the polymeric materials listed above. A layer 246 of a catalyst for oxidation-reduction reaction is disposed on coating 244. Suitable catalysts for oxidation-reduction reaction are platinum and palladium. It is preferred that the catalyst metals are disposed as very fine particles, such as having a size on the order of less than about 10 nanometers.

Seals 250 are provided around the periphery of DSPVC 210 to define space 260, which contains an electrolyte, which serves as a charge carrier for returning electrons from an external circuit. The electrolyte comprises a species that can undergo oxidation-reduction reaction, such as a combination of an iodide salt and iodine, or a bromide salt and bromine. Salts such as LiI, NaI, KI, Cal₂, LiBr, NaBr, KBr, or CaBr₂ are often used. Seals 250 are made of a material resistant to chemical attack by the electrolyte, such as an epoxy resin.

Substantially transparent substrate 240 also serves as the first substrate for the third PV cell 310, and provides electrical isolation from the second PV cell 210. Substrate 240 has a coating 324 of a substantially transparent, electrically conductive material that is selected from among the materials disclosed above (for layers 124 and 224) and disposed on the second surface thereof. Thus, cell 310 is electrically insulated from cell 210.

A semiconductor layer 330 is disposed on coating 324. The semiconductor material of layer 330 is coated by adsorption of a photoactivatable dye on the surface thereof.

A second substrate 340 having an electrically conductive coating 344 disposed on a first surface thereof is disposed opposite and apart from semiconductor layer 330. Electrically conductive coating 344 serves as the second electrode of DSPVC 310, and can be made of one of the conductive oxides listed above or of a substantially transparent metal layer. Substrate 340 may be made of a substantially transparent glass or polymeric material, such as one of the polymeric materials listed above. A layer 346 of a catalyst for oxidation-reduction reaction is disposed on coating 344. Suitable catalysts for oxidation-reduction reaction are platinum and palladium. It is preferred that the catalyst metals are disposed as very fine particles, such as having a size on the order of less than about 10 nanometers.

Seals 350 are provided around the periphery of DSPVC 310 to define space 360, which contains an electrolyte, which serves as a charge carrier for returning electrons from an external circuit. The electrolyte comprises a species that can undergo oxidation-reduction reaction, such as a combination of an iodide salt and iodine, or a bromide salt and bromine. Salts such as LiI, NaI, KI, Cai₂, LiBr, NaBr, KBr, or CaBr₂ are often used. Seals 350 are made of a material resistant to chemical attack by the electrolyte, such as an epoxy resin.

Each of PV cells 110, 210, and 310 is electrically connected through its own pair of electrodes to an external circuit to provide electrical power thereto. Furthermore, each of PV cells 110, 210, and 310 is preferably provided with an electrical control device to provide substantially maximum power, as measured by the product of voltage and current, from the individual cell. Therefore, the total PV device 90 can operate at or near its maximum efficiency.

When the first substrate of the first PV cell and the second substrate of the last PV cell in the stack are made of polymeric materials, they are preferably coated with barrier coatings that provide a barrier to the diffusion of chemically reactive species of the environment into the internal portions of the PV device. Among those chemical reactive species are oxygen; water vapor; solvents; acid gases, such as hydrogen sulfide, SOX, NOX, etc., which can attack and degrade the sensitive components of the organic PV cell, such as the organic dye, the catalyst layer, the electrodes, or the electrolyte.

In one embodiment of the present invention, a barrier coating of the first substrate of the first PV cell and the second substrate of the last PV cell in the stack comprises a multilayer stack of a plurality of alternating organic and inorganic layers. A barrier coating also can be one the composition of which varies continuously across its thickness, such as from a predominantly organic composition to a predominantly inorganic composition. The thickness of the barrier coating is in the range from about 10 nm to about 1000 nm, preferably from about 10 nm to about 500 nm, and more preferably from about 10 nm to about 200 nm. It is desirable to choose a coating thickness that does not impede the transmission of light through the substrate that receives light, such as a reduction in light transmission less than about 20 percent, preferably less than about 10 percent, and more preferably less than about 5 percent. The organic layers of the multilayer stack comprises a polymeric material selected from the group consisting of polyacrylates, polyester, polyethyleneterephthalate, polyolefins, and combinations thereof. The organic layers can be deposited as a monomer or oligomer of the final polymer onto a substrate by a method selected from the group consisting of spin coating, dip coating, vacuum deposition, ink-jet printing, and spraying, followed by a polymerization reaction of the monomer or oligomer. The thickness of an organic layer is in the range from about 10 nm to about 500 nm. The inorganic layers typically comprise oxide; nitride; carbide; boride; or combinations thereof of elements of Groups IIA, IIIA, IVA, VA, VIA, VIIA, IB, and IIB; metals of Groups IIIB, IVB, and VB; and rare-earth metals. For example, silicon carbide can be deposited onto a substrate by recombination of plasmas generated from silane (SiH₄) and an organic material, such as methane or xylene. Silicon oxycarbide can be deposited from plasmas generated from silane, methane, and oxygen or silane and propylene oxide. Silicon oxycarbide also can be deposited from plasmas generated from organosilicone precursors, such as tetraethoxysilane (TEOS), hexamethyldisiloxane (HMDSO), hexamethyldisilazane (HMDSN), or octamethylcyclotetrasiloxane (D4). Silicon nitride can be deposited from plasmas generated from silane and ammonia. Aluminum oxycarbonitride can be deposited from a plasma generated from a mixture of aluminum tartrate and ammonia. Other combinations of reactants may be chosen to obtain a desired coating composition. The choice of the particular reactants depends on the final composition of the barrier coating. The thickness of an inorganic layer is typically in the range from about 10 nm to about 200 nm, preferably from about 10 nm to about 100 nm. The inorganic layer can be deposited onto a substrate by a method selected from the group consisting of plasma-enhanced chemical-vapor deposition (“PECVD”), radio-frequency plasma-enhanced chemical-vapor deposition (“RFPECVD”), expanding thermal-plasma chemical-vapor deposition (“ETPCVD”), sputtering including reactive sputtering, electron-cyclotron-resonance plasma-enhanced chemical-vapor deposition (“ECRPECVD”), inductively coupled plasma-enhanced chemical-vapor deposition (“ICPECVD”), or combinations thereof.

In another embodiment of the present invention, as shown perspectively in FIG. 4, a PV device 500 comprises a plurality of PV modules 550 that are arranged in tandem. FIG. 4 shows modules 550 separated from one another. However, it should be understood that modules 550 may be disposed adjacent to one another without any substantial gaps between them. Each module 550 comprises a plurality of PV cells 10 disposed on a support 580. PV cells 10 of a module 550 substantially overlap with PV cells 10 of other modules 550. The overlapping PV cells of all tandem PV cell modules 550 comprise photoactivatable dyes that have strong absorption of light in different wavelength ranges of the spectrum of light received by PV device 500 so that substantially all of the received light is harvested. Preferably, all PV cells of a module are provided with one type of photoactivatable dye. PV cells 10 of a module 550 are electrically connected (e.g., in parallel, in series, or a combination thereof) such that a desired voltage, current, or power (as measured by the product of voltage and current) is achieved.

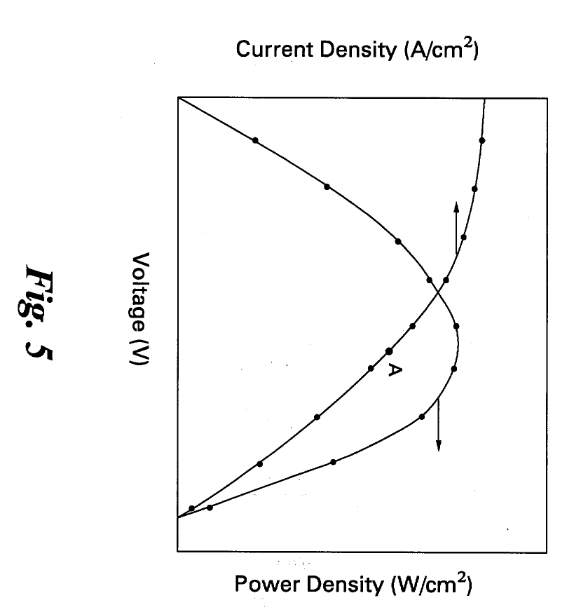

FIG. 5 shows the characteristic current-voltage curve and the corresponding characteristic power curve for a PV cell that can be used as a PV cell in a tandem cell module of the present invention. This PV cell can be operated at point A on the characteristic current-voltage curve to produce the maximum output power. Similarly, each of the other PV cells in the tandem cell module has a definable operating point for maximum output power. Thus, each PV cell can be operated at its point of maximum output power to provide a maximum output power form the entire tandem cell module of the present invention. Non-limiting examples of implementation for obtaining controllable output power from tandem cell modules of the present invention are now described.

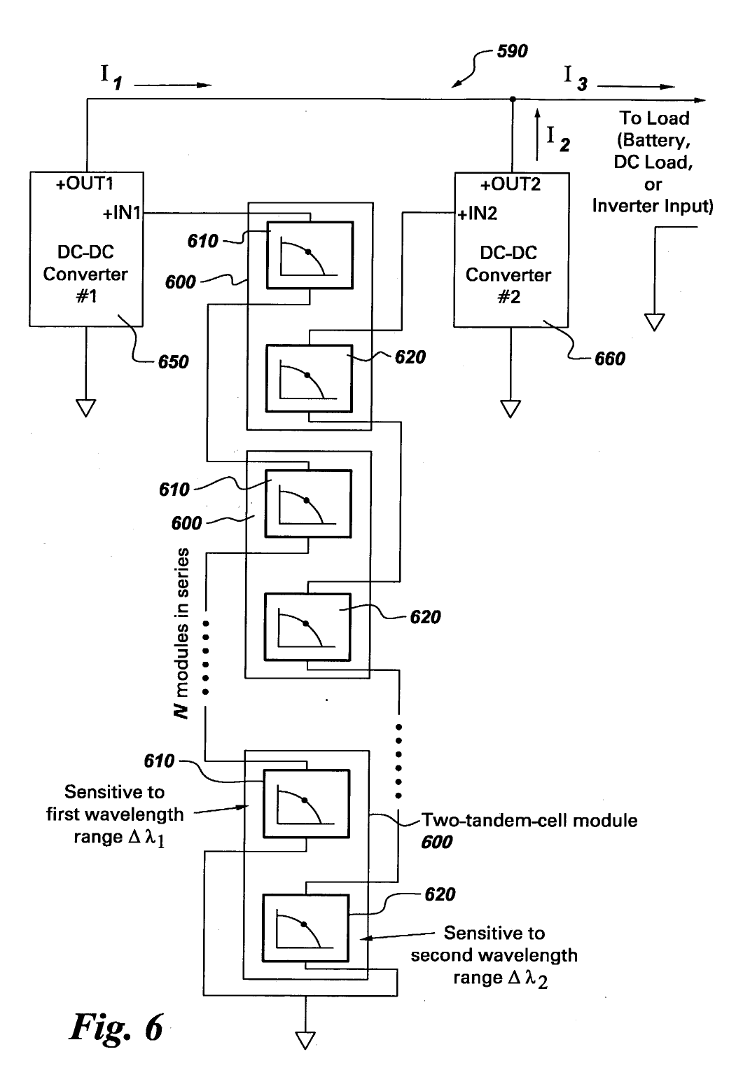

FIG. 6 schematically shows a first system 590 implementing a use of the tandem cell modules of the present invention. The system comprises a plurality of tandem cell devices 600, each of which comprises a plurality of PV cells (610, 620) arranged in tandem. Two tandem PV cells (610, 620) are shown in FIG. 6 for each of devices 600 for illustration purposes. However, it should be understood that the invention is applicable for any number of tandem PV cells greater than or equal to two. In addition, each of the PV cells (610, 620) can be replaced with a PV cell module 550 that comprises a plurality of PV cells 10 arranged on a common support, as illustrated in FIG. 4. The plurality of PV cells 10 of a single PV cell module 550 preferably is excitable by the same wavelength range. All PV cells 610 of the first type that are capable of absorbing light of a first wavelength range Δλ₁ are electrically connected in a first series, which is connected to the input of a first DC-DC converter 650. Converter 650 extracts approximately maximum power from the first series by operating PV cells 610 at about the point of maximum power on their characteristic current-voltage curve, as illustrated in FIG. 5. Similarly, all PV cells 620 of the second type that are capable of absorbing light of a second wavelength range Δλ₂ are electrically connected in a second series, which is connected to the input of a second DC-DC converter 660. Converter 660 extracts approximately maximum power from the second series by operating PV cells 620 at about the point of maximum power on their characteristic current-voltage curve. The output current I₁ and I₂ from converters 650 and 660 are combined to be supplied to a DC load. Converters of the boost circuit type or phase-shifted bridge type, for example, can be used for converters 650 and 660. The characteristic values (e.g., switching frequency, duty cysle, capacitance, inductance, etc.) of these converters are chosen to provide a desired output voltage or output current in view of the characteristic voltage and current of PV cells 610 and 620. Several types of passive DC-DC converters are taught in Philip T. Krein, “Elements of Power Electronics,” pp. 118-161, Oxford University Press, New York (1998). A suitable type of smart converters that are capable of extracting maximum power from a DC source, such as one or more PV cells 610 or 620 under circumstances of changing irradiation, is disclosed in U.S. Pat. No. 4,404,472; which is incorporated herein by reference.

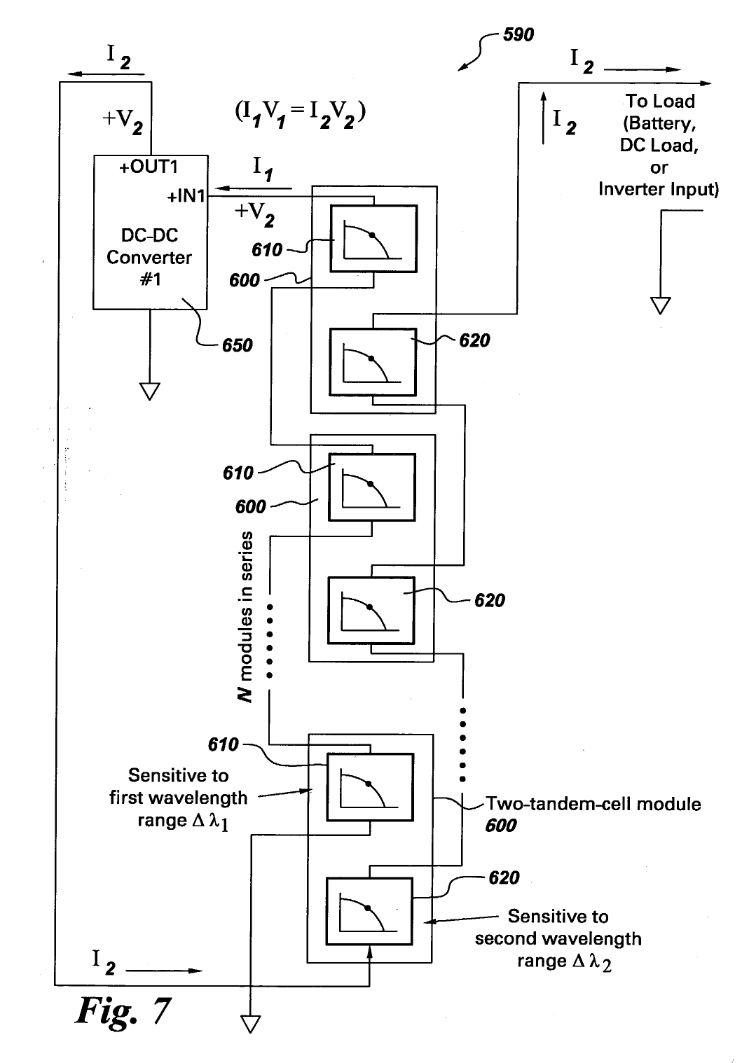

FIG. 7 schematically shows a second system 590 implementing another use of the tandem cell modules of the present invention. The system comprises a plurality of tandem cell devices 600, each of which comprises a plurality of PV cells (610, 620) arranged in tandem. Two tandem PV cells are shown in FIG. 7 for each of devices 600 for illustration purposes. However, it should be understood that the invention is applicable for any number of tandem PV cells greater than or equal to two. In addition, each of the PV cells (610, 620) can be replaced with a PV cell module 550 that comprises a plurality of PV cells 10 arranged on a common support 580, as illustrated in FIG. 4. All PV cells 610 of the first type that are capable of absorbing light of a first wavelength range Δλ₁ are electrically connected in a first series, which is connected to the input of a first DC-DC converter 650. Converter 650 extracts approximately maximum power from the first series by operating PV cells 610 at about the point of maximum power on their characteristic current-voltage curve, as illustrated in FIG. 5. Similarly, all PV cells 620 of the second type that are capable of absorbing light of a second wavelength range Δλ₂ are electrically connected in a second series. Output current I₂ from DC-DC converter 650 is controlled through the second series of PV cells 620, providing a voltage level determinable from the characteristic current-voltage curve of PV cells 620 such that maximum power is also extracted from the second series of PV cells.

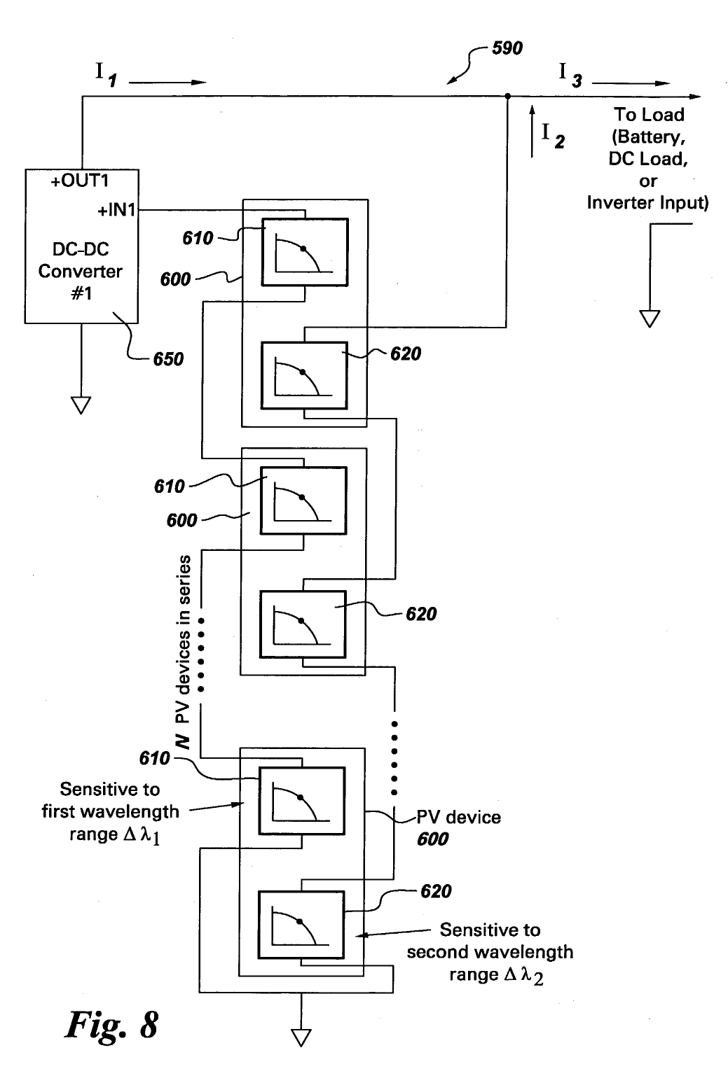

FIG. 8 schematically shows a third system 590 implementing another use of the tandem cell modules of the present invention. The system comprises a plurality of tandem cell devices 600, each of which comprises a plurality of PV cells (610, 620) arranged in tandem. Two tandem PV cells (610, 620) are shown in FIG. 8 for each of devices 600 for illustration purposes. However, it should be understood that the invention is applicable for any number of tandem PV cells greater than or equal to two. In addition, each of the PV cells (610, 620) can be replaced with a PV cell module 550 that comprises a plurality of PV cells 10 arranged on a common support 580, as illustrated in FIG. 4. All PV cells 610 of the first type that are capable of absorbing light of a first wavelength range Δλ₁ are electrically connected in a first series, which is connected to the input of a first DC-DC smart converter 650. Converter 650 extracts approximately maximum power from the first series by operating PV cells 610 at about the point of maximum power on their characteristic current-voltage curve (represented by current I₁ and voltage V₁), as illustrated in FIG. 5. Similarly, all PV cells 620 of the second type that are capable of absorbing light of a second wavelength range Δλ₂ are electrically connected in a second series. Smart converter 650 adjusts output voltage V₂ to produce an output current I₂, which is drawn through the second series of PV cells 620, such that output current I₂ corresponds to the point of maximum power on the characteristic current-voltage curve of cells 620. Alternatively, if the load is active (i.e., an input is provided to a DC-DC converter or to an inverter) the active load can be controlled to draw maximum power from the second PV series string while the first DC-DC converter is extracting power from the first PV cell series string.

Alternatively, if the load is active (i.e.

### EXAMPLE

### Manufacture of a DSPVC

Commercial SnO₂-coated glass (Pilkington Glass, Hartford, Conn.) was cut into pieces having dimensions of about 7.5 cm×10 cm, cleaned with detergent and water, and dried. Lines of a silver paste (DuPont 7713) were printed on the SnO₂ side of the coated glass pieces by screen printing. Every two lines of silver paste were connected together at one end by a transverse line of the same silver paste. The thickness of the silver-paste lines was about 10 micrometers. The silver lines served to increase the electrical conductivity through the SnO₂ coating, and thus their widths were not critical. Holes were drilled into a number of glass pieces that were printed with silver-paste lines and located between every two connected silver-paste lines. The glass pieces without holes served as the first electrodes of the final PV cells, and those with holes as the second electrodes. The glass pieces with the silver-paste lines printed thereon were fired in a furnace under a nitrogen atmosphere according to the following temperature program: ramping at 8 C/minute from ambient temperature to 200 C, holding at 200 C for 15 minutes, ramping at 16 C/minute to 525 C, holding at 525 C for 90 minutes, and cooling down slowly under nitrogen until temperature fell below than 200 C.

Platinum was deposited between every two connected silver lines on the glass pieces thus produced that had been drilled with holes, as follows. A solution of 5 mM of chloroplatinic acid (Aldrich catalog number 25,402-9) in isopropanol was dispensed dropwise and spread onto the SnO₂-coated surface by the doctor blade method. The platinum-coated pieces were dried in air and then fired in a furnace under a nitrogen atmosphere according to the following program: ramping at 10 C/minute from ambient temperature to 390 C, cooling down to below 200 C, and transferring to a glove box purged with nitrogen for further PV cell assembly.

Titanium dioxide was deposited between every two connected silver lines on the glass pieces that had not been drilled with holes, as follows. Titanium dioxide paste (Solaronix DSP) was deposited by screen printing on the SnO₂-coated surface to a thickness of less than about 10 micrometers. The glass pieces with TiO₂paste deposited thereon were placed in an ethanol-rich atmosphere for 10-20 minutes, and then fired in a furnace under oxygen atmosphere according to the following program: ramping at 10 C/minute from ambient temperature to 130 C, ramping at 0.5 C/minute to 140 C, ramping at 10 C/minute to 420 C, ramping at 0.5 C/minute to 440 C, cooling down at 2 C/minute until below 200 C, and then transferring to the glove box purged with nitrogen. The relative humidity inside the glove box was kept under 3%.

Photoactivatable dye N719 (bis(isothiocyanato)-ruthenium (II)-bis-2,2′-bipyridine-4,4′-dicarboxylic acid, available from Greatcell Solar SA, Yverdon-Les-Bains, Switzerland, or Solaronix SA, Aubonne, Switzerland) was adsorbed on the TiO₂ layer as follows. The TiO₂-coated glass pieces were soaked overnight in a 0.5 mM solution of N719 dye (0.05943 g of N719 dye, 50 ml of acetonitrile, and 50 ml of 2-methyl-2-propanol) inside a desiccator that is purged with a stream of nitrogen containing ethanol.

A gasket having a thickness of about 40 micrometers, made of Surlyn® polymer (a thermoplastic polymer film available from DuPont; other thermoplastic polymers, such as Nucrel® from DuPont or Primacor® from Dow Chemical, also can be used) was provided as a spacer between a TiO₂-coated glass piece and a Pt-coated glass piece. Portions of the gasket were removed at locations of the matching TiO₂ and Pt portions of the coated glass pieces. The assembly of TiO₂-coated glass piece/gasket/Pt-coated glass piece was hot pressed at 130 C for 80 seconds to adhere the gasket to the electrodes (TiO₂-coated glass piece and Pt-coated glass piece).

An electrolyte solution comprising 0.05 LiI, 0.05 M iodine, 0.5tert-butyl pyridine, and 0.5 M tetrapropylammonium iodide was introduced into the space between the electrodes via the holes provided in the Pt-coated glass piece. The holes were then sealed with plastic plugs and hot pressed at 100 C for about 10 seconds.

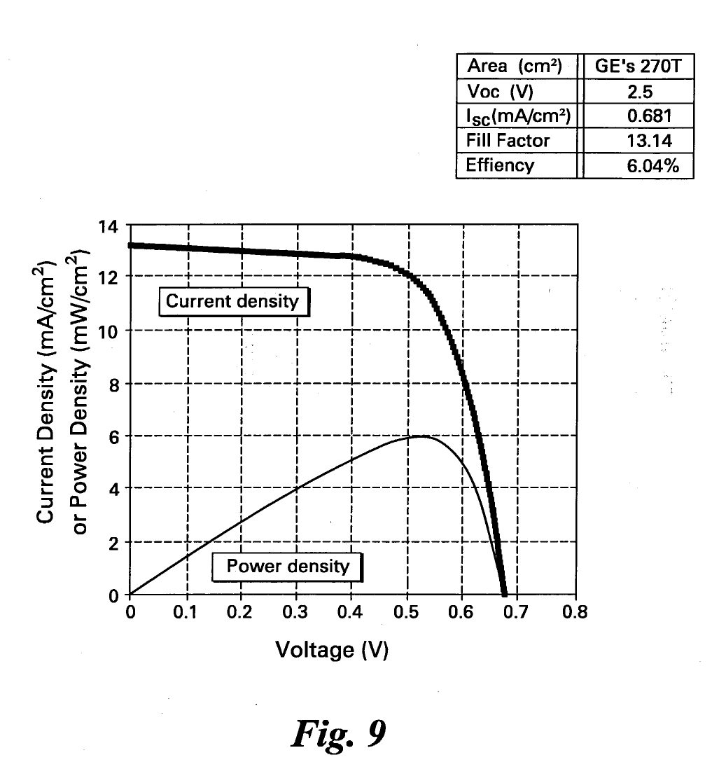

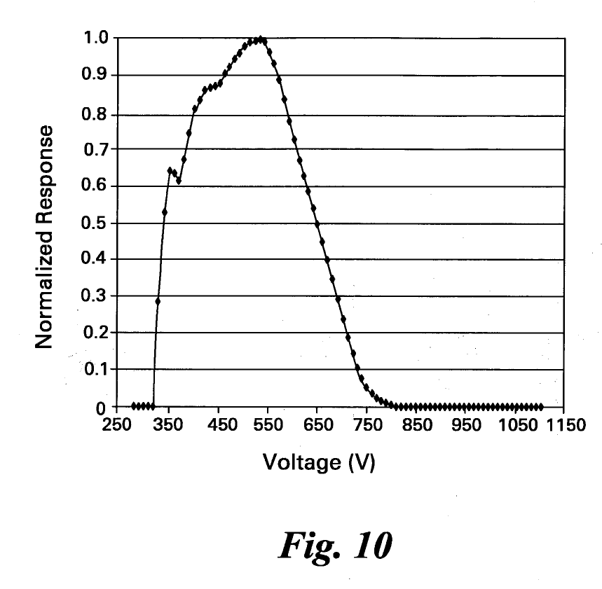

The performance of the PV cell thus produced was measured with AM 1.5 solar radiation. FIGS. 9 and 10 show the current-voltage and power curves, and the normalized quantum efficiency of this PV cell. It can be observed that the N719 dye absorbs strongly in the wavelength range from about 450 nm to about 550 nm.

PV cells that include other types of dyes, chosen among those disclosed earlier, can be made according to the same procedure to harvest light in complementary ranges and disposed in tandem with the PV cell of the Example to absorb substantially the whole spectrum of light that is received by the stack.

As an alternative to using a commercially available-glass substrate coated with a conducting layer (e.g., SnO₂ of the above Example), the substrate (such as glass or a polymeric material) can be deposited with a conducting material by a method selected from the group consisting of physical vapor deposition such as sputtering or vacuum vapor deposition, and chemical vapor deposition, such as PECVD, RFPECVD, ETPCVD, ECRPECVD, or ICPECVD, and combinations thereof.

An alternative method for depositing a layer of a paste such as the silver paste or the TiO₂ paste is the direct writing method, which dispenses the paste through a micrometer-sized nozzle (about 10 to about 250 micrometers) the location of which can be controlled substantially precisely by a microcomputer. This method also can form films having substantially uniform thickness.

In another embodiment of the present invention, some PV cells of the stack of tandem PV cells are of the type of DSPVCs, as illustrated in FIG. 1, and some of the other PV cells of the stack are of the type comprising organic electron donor and electron acceptor semiconducting materials, as illustrated in FIG. 2. All of the tandem PV cells of the stack absorb substantially the whole spectrum of light that is received by the stack.

While various embodiments are described herein, it will be appreciated from the specification that various combinations of elements, variations, equivalents, or improvements therein may be made by those skilled in the art, and are still within the scope of the invention as defined in the appended claims.

What is claimed is:

1. A photovoltaic (“PV”) power source comprising a plurality of PV cell modules that are arranged in tandem; wherein the PV cell modules are electrically insulated from each other, and each of the PV cell modules comprises at least a PV cell that comprises:
a first electrode;
an electron donor material disposed on and in contact with the first electrode;
an electron acceptor material disposed in contact with the electron donor material; and
a second electrode disposed in contact with the electron acceptor material.

2. The PV power source according to claim 1, wherein the electron donor material comprises a semiconductor material disposed in electrical contact with the first electrode; the semiconductor material has a coating comprising a photoactivatable dye; the electron acceptor material is an electrolyte being capable of undergoing an oxidation-reduction reaction; and the second electrode further comprises a catalyst for the oxidation-reduction reaction.

3. The PV power source according to claim 2, wherein photoactivatable dyes of the PV cell modules are capable of absorbing light having different wavelength ranges.

4. The PV power source according to claim 2, wherein a spectrum of light received by the PV power source comprises the wavelength ranges of light absorbed by the photoactivatable dyes of all of the PV cell modules.

5. The PV power source according to claim 2, wherein the photoactivatable dyes of the PV cell modules are different and are independently selected from the group consisting of organometallic complexes having a formula of MX₃Lₜ, wherein M is a transition metal selected from the group consisting of ruthenium, osmium, iron, rhenium, and technetium; Lₜ is tridentate ligand comprising heterocycles selected from the group consisting of pyridine, thiophene, imidazole, pyrazole, triazole, carrying at least one functional group selected from the group consisting of carboxylic, phosphoric, hydroxamic acid, and chelating groups; and X is a co-ligand independently selected from the group consisting of NCS, Cl, Br, I, CN, NCO, H₂O, NCH, unsubstituted pyridine, pyridine substituted with at least one group selected from the group consisting of vinyl, primary amine, secondary amine, tertiary amine, OH, and C₁₋₃₀ alkyl.

6. The PV power source according to claim 2, wherein the photoactivatable dyes of the PV cell modules are different and are independently selected from the group consisting of organometallic complexes having a formula of MXYLₜ, wherein M is a transition metal selected from the group consisting of ruthenium, osmium, iron, rhenium, and technetium; Lₜ is tridentate ligand comprising heterocycles selected from the group consisting of pyridine, thiophene, imidazole, pyrazole, triazole, carrying at least one functional group selected from the group consisting of carboxylic, phosphoric, hydroxamic acid, and chelating groups; and X is a co-ligand independently selected from the group consisting of NCS, Cl, Br, I, CN, NCO, H₂O, NCH, unsubstituted pyridine, pyridine substituted with at least one group selected from the group consisting of vinyl, primary amine, secondary amine, tertiary amine, OH, and C₁₋₃₀ alkyl; and Y is a co-ligand selected from the group consisting of o-phenanthroline, unsubstituted 2,2′-bipyridine, and 2,2′-buipyridine substituted with at least one C₁₋₃₀ alkyl group.

7. The PV power source according to claim 2, wherein the photoactivatable dyes of the PV cell modules are different and are independently selected from the group consisting of azo dyes, quinone dyes, quinoneimine dyes, quinacridone dyes, squarylium dyes, cyanine dyes, merocyanine dyes, triphenylmethane dyes, xanthene dyes, porphyrin dyes, phthalocyanine dyes, perylene dyes, indigo dyes, and naphthalocyanine dyes.

8. The PV power source according to claim 2, wherein the first electrode comprises a substantially transparent material.

9. The PV power source according to claim 8, wherein the substantially transparent material is selected from the group consisting of indium tin oxide, tin oxide, indium oxide, zinc oxide, indium zinc oxide, zinc indium tin oxide, antimony oxide, mixtures thereof, silver, gold, aluminum, copper, steel, and nickel.

10. The PV power source according to claim 2, wherein the second electrode comprises a material selected from the group consisting of indium tin oxide, tin oxide, indium oxide, zinc oxide, indium zinc oxide, zinc indium tin oxide, antimony oxide, mixtures thereof, silver, gold, aluminum, copper, steel, and nickel.

11. The PV power source according to claim 2, wherein the semiconductor material is selected from the group consisting of oxides of the transition metal elements.

12. The PV power source according to claim 2, wherein the semiconductor material is selected from the group consisting of oxides of titanium, zirconium, halfnium, strontium, zinc, indium, yttrium, lanthanum, vanadium, niobium, tantalum, chromium, molybdenum, tungsten, iron, nickel, silver, and mixed oxides thereof.

13. The PV power source according to claim 2, wherein the electrolyte comprises a mixture selected from the group consisting of a mixture of iodine and an iodide salt, and a mixture of bromine and a bromide salt.

14. The PV power source according to claim 2, wherein each PV cell of a PV cell module further comprises a first substantially transparent substrate on which the first electrode is disposed, a second substrate on which the second electrode is disposed, and a seal disposed around an edge of each PV cell to contain the electrolyte.

15. The PV power source according to claim 14, wherein each of the first substrate and the second substrate comprises a material selected from the group consisting of glass and substantially transparent polymeric materials.

16. The PV power source according to claim 15, wherein each of the first substrate and the second substrate comprises a substantially transparent polymeric material, and wherein two outside substrates exposed to an environment are coated with a barrier coating.

17. The PV power source according to claim 16, wherein the barrier coating comprises a multilayer of a plurality of alternating layers of at least an organic polymeric material an at least an inorganic material.

18. The PV power source according to claim 16, wherein the barrier coating comprises a material a composition of which varies continuously across a thickness of the barrier coating from a substantially organic material to a substantially inorganic material.

19. A PV power source comprising a plurality of PV cell modules that are arranged in tandem; wherein the PV cell modules are electrically insulated from each other, and each of the PV cell modules comprises at least a PV cell that comprises:
a first electrode;
a semiconductor material disposed in electrical contact with the first electrode, the semiconductor material adsorbing a photoactivatable dye;
a second electrode disposed opposite to and spaced apart from the semiconductor material, a catalyst for an oxidation-reduction reaction being disposed on a surface of the second electrode opposite to the semiconductor material; and
an electrolyte disposed in a space between the semiconductor material and the second electrode, the electrolyte being capable of undergoing the oxidation-reduction reaction;
wherein the first electrode comprises a substantially transparent layer of a material selected from the group consisting of indium tin oxide, tin oxide, indium oxide, zinc oxide, indium zinc oxide, zinc indium tin oxide, antimony oxide, mixtures thereof, silver, gold, aluminum, copper, steel, and nickel;
the semiconductor material is selected from the group consisting of oxides of the transition metal elements;
the photoactivatable dyes of the PV cell modules are different and capable of absorbing light having different wavelength ranges, which comprise a spectrum of light received by the PV power source, the photoactivatable dyes being independently selected from the group consisting of organometallic complexes having a formula selected from the group consisting of MX₃Lₜ and MXYLₜ, wherein M is a transition metal selected from the group consisting of ruthenium, osmium, iron, rhenium, and technetium; Lₜ is tridentate ligand comprising heterocycles selected from the group consisting of pyridine, thiophene, imidazole, pyrazole, triazole, carrying at least one functional group selected from the group consisting of carboxylic, phosphoric, hydroxamic acid, and chelating groups; X is a co-ligand independently selected from the group consisting of NCS, Cl, Br, I, CN, NCO, H₂O, NCH, unsubstituted pyridine, pyridine substituted with at least one group selected from the group consisting of vinyl, primary amine, secondary amine, tertiary amine, OH, and C₁₋₃₀ alkyl; and Y is a co-ligand selected from the group consisting of o-phenanthroline, unsubstituted 2,2′-bipyridine, and 2,2′-buipyridine substituted with at least one C₁₋₃₀ alkyl group.

20. A photovoltaic (“PV”) power source comprising a plurality of PV cell modules that are arranged in tandem; wherein the PV cell modules are electrically insulated from each other, and each of the PV cell modules comprises at least a PV cell that comprises:
a first electrode;
a semiconductor material disposed in electrical contact with the first electrode, the semiconductor material adsorbing a photoactivatable dye;
a second electrode disposed opposite to and spaced apart from the semiconductor material, a catalyst for an oxidation-reduction reaction being disposed on a surface of the second electrode opposite to the semiconductor material; and
an electrolyte disposed in a space between the semiconductor material and the second electrode, the electrolyte being capable of undergoing the oxidation-reduction reaction;
wherein the first electrode comprises a substantially transparent layer of a material selected from the group consisting of indium tin oxide, tin oxide, indium oxide, zinc oxide, indium zinc oxide, zinc indium tin oxide, antimony oxide, mixtures thereof, silver, gold, aluminum, copper, steel, and nickel;
the semiconductor material is selected from the group consisting of oxides of the transition metal elements;
the photoactivatable dyes of the PV cell modules are different and capable of absorbing light having different wavelength ranges, which comprise a spectrum of light received by the PV power source, the photoactivatable dyes being independently selected from the group consisting of azo dyes, quinone dyes, quinoneimine dyes, quinacridone dyes, squarylium dyes, cyanine dyes, merocyanine dyes, triphenylmethane dyes, xanthene dyes, porphyrin dyes, phthalocyanine dyes, perylene dyes, indigo dyes, and naphthalocyanine dyes.

21. A PV power source comprising a plurality of PV cell modules that are arranged in tandem; wherein the PV cell modules are electrically insulated from each other, and each of the PV cell modules comprises a plurality of PV cells arranged on a support, each of the PV cells comprising:
a first electrode;
a semiconductor material disposed in electrical contact with the first electrode, the semiconductor material adsorbing a photoactivatable dye;
a second electrode disposed opposite to and spaced apart from the semiconductor material, a catalyst for an oxidation-reduction reaction being disposed on a surface of the second electrode opposite to the semiconductor material; and
an electrolyte disposed in a space between the semiconductor material and the second electrode, the electrolyte being capable of undergoing the oxidation-reduction reaction;
wherein all of the PV cells of a PV cell module carry one type of photoactivatable dye, the photoactivatable dyes of all of the PV cell modules absorb substantially a spectrum of light received by the PV power source, and the PV cells of one PV cell module overlap with the PV cells of other PV cell modules.

22. The PV power source according to claim 1, wherein the electron donor material comprises a polymer selected from the group consisting of polyphenylene, poly(phenylene vinylene), polythiophene, polysilane, poly(thienylene vinylene), poly(isothianaphthene), derivatives thereof, and copolymers thereof; and the electron acceptor material comprises a polymer selected from the group consisting of derivatives of poly(phenylene vinylene) having a functional group selected from the group consisting of CN and CF₃.

23. The PV power source according to claim 1, wherein the electron donor material comprises a photoactivatable dye; and the electron acceptor material comprises a polymer selected from the group consisting of derivatives of poly(phenylene vinylene) having a functional group selected from the group consisting of CN and CF₃.

24. The PV power source according to claim 23, wherein PV cells of one PV cell module has one photoactivatable dye, and PV cells of different PV cell modules have different photoactivatable dyes.

25. A PV power source comprising:
a plurality of PV cell modules that are arranged in tandem; and
at least a power converter that is capable of extracting substantially maximum power from a PV cell module;
wherein the PV cell modules are electrically insulated from each other, and each of the PV cell module comprises at least a PV cell that comprises:
a first electrode;
an electron donor material disposed on and in contact with the first electrode;
a layer of an electron acceptor material disposed in contact with the electron donor material; and
a second electrode disposed in contact with the electron acceptor material.

26. A PV power generation system comprising:
a plurality of PV devices, each of the PV devices comprising at least a first PV cell module and at least a second PV cell module that are arranged in tandem, the first PV cell modules and the second PV cell modules of the PV devices absorbing different wavelength ranges of a spectrum of light received by the PV devices, the first PV cell modules of the plurality of PV devices being connected in series, the second PV cell modules of the plurality of PV devices being connected in series; and
at least a power converter that is capable of extracting substantially maximum power from the series of first PV cell modules;
wherein the PV cell modules are electrically insulated from each other, and each of the PV cell module comprises at least a PV cell that comprises:
a first electrode;
an electron donor material disposed on and in contact with the first electrode;
an electron acceptor material disposed in contact with of the electron donor material; and
a second electrode disposed in contact with the electron acceptor material.

27. A PV power generation system comprising:
a plurality of PV devices, each of the PV devices comprising at least a first PV cell module and at least a second PV cell module that are arranged in tandem, the first PV cell modules and the second PV cell modules of the PV devices absorbing different wavelength ranges of a spectrum of light received by the PV devices, the first PV cell modules of the plurality of PV devices being connected in series, the second PV cell modules of the plurality of PV devices being connected in series; and
a power converter that is capable of extracting substantially maximum power from each of the series of PV cell modules;
wherein the PV cell modules are electrically insulated from each other, and each of the PV cell module comprises at least a PV cell that comprises:
a first electrode;
an electron donor material disposed on and in contact with the first electrode;
an electron acceptor material disposed in contact with the electron donor material; and
a second electrode disposed in contact with the electron acceptor material.

28. A PV power generation system comprising:
at least a first PV cell module and at least a second PV cell module that are arranged in tandem; and
at least a power converter that is capable of extracting substantially maximum power from the first PV cell modules and that provides an output current corresponding substantially to a maximum power of the at least second PV cell module, the output current being drawn through the at least second PV cell module;
wherein the PV cell modules are electrically insulated from each other, and each of the PV cell module comprises at least a PV cell that comprises:
a first electrode;
an electron donor material disposed on and in contact with the first electrode;
an electron acceptor material disposed in contact with the electron donor material; and
a second electrode disposed in contact with the electron acceptor material.

29. A PV power generation system comprising:
a plurality of PV cell modules that are arranged in tandem; and
at least a power converter that is capable of extracting substantially maximum power from a PV cell module;
wherein the PV cell modules are electrically insulated from each other, and each of the PV cell module comprises at least a PV cell that comprises:
a first electrode;
an electron donor material disposed on and in contact with the first electrode;
an electron acceptor material disposed in contact with the electron donor material; and
a second electrode disposed in contact with of the electron acceptor material.
